(19) United States
(12) Patent Application Publication
(10) Pub. No.: US 2026/0126842 A1
(43) Pub. Date: May 7, 2026

(54) SYSTEM AND METHOD FOR DETECTING POWER STABILITY

(71) Applicant: Aivres Systems Inc., Fremont, CA (US)

(72) Inventor: I-Chang YANG, New Taipei City (TW)

(73) Assignee: Aivres Systems Inc., Fremont, CA (US)

(21) Appl. No.: 19/436,351

(22) Filed: Dec. 30, 2025

(51) Int. Cl. G06F 1/28; G01R 19/00; G01R 19/165; G06F 1/30

(52) U.S. Cl. CPC G06F 1/28; G01R 19/0084; G01R 19/16528; G01R 19/16585; G06F 1/30

(57) ABSTRACT

Systems and methods for monitoring power stability are provided. In some embodiments, a detection system is used to determine a reference voltage based on an output voltage from a power source, monitor an input voltage corresponding to a point along a power distribution line between the power source and a load, detect the input voltage triggering a condition set forth by the reference voltage, and send an alert based on the input voltage triggering the condition a preset number of times within a preset period.

### TECHNICAL FIELD

The disclosed embodiments relate generally to computer systems, and more particularly, to monitoring the operation of the computer systems.

### BACKGROUND

Power on server motherboards is typically distributed through the following steps. First, the output of the server power supply, such as a Common Redundant Power Supply (CRPS), is connected to a Power Distribution Board (PDB). The PDB then delivers the required power to the motherboard via power cables. These power levels are monitored by the Baseboard Management Controller (BMC).

Power stability is critical to the reliable operation of a server. For example, insufficient power can lead to system failures, while excessive voltage may damage downstream electronic components. Several factors can contribute to power instability. A common cause is the increase in contact resistance (or wire resistance) along the power transmission path—particularly after prolonged use of the server. This can result from elevated operating temperatures, aging of power cables, or poor contact at the power connectors, ultimately leading to excessive voltage drop.

However, when the server is operating under low load, the management controller is unable to detect potential undervoltage issues that may occur under high load in advance. As a result, it cannot proactively trigger fault handling procedures for improvement or prevention.

### SUMMARY

In an exemplary embodiment, a method is provided for monitoring power stability. The method includes determining, by a detection system, a reference voltage based on an output voltage from a power source, monitoring, by the detection system, an input voltage corresponding to a point along a power distribution line between the power source and a load, detecting, by the detection system, the input voltage triggering a condition set forth based on the reference voltage, and sending, by the detection system, an alert based on the input voltage triggering the condition a preset number of times within a preset period.

According to an embodiment of the method, detecting the input voltage triggering the condition set forth based on the reference voltage includes at least one of detecting the input voltage exceeding the reference voltage, or detecting the input voltage falling below the reference voltage.

According to an embodiment of the method, a number of times corresponding to the input voltage triggering the condition is counted by a counter in the detection system. The counter is reset periodically according to the preset period.

According to an embodiment of the method, sending the alert based on the input voltage triggering the condition the preset number of times within the preset period includes sending, by the counter, a signal to a controller in response to the number of times counted by the counter reaching the preset number of times within the preset period, and sending, by the controller, the alert to a user or initiate a system response.

According to an embodiment of the method, the load is a motherboard of a computing system.

According to an embodiment of the method, the method also includes monitoring, by the detection system, a plurality of input voltages between the power source and the load.

According to an embodiment of the method, the detection system comprises a first ripple detector and a second ripple detector. The first ripple detector is configured to monitor the input voltage when the load is in an active state. The second ripple detector is configured to monitor the input voltage when the load in a lower-power state.

According to an embodiment of the method, the detection system is configured to monitor the input voltage at a first setting, when the load is in an active state, and monitor the input voltage at a second setting, when the load in a lower-power state.

In a further exemplary embodiment, a system is provided for monitoring power stability. The system includes a reference voltage circuit, a ripple detector, and a counter. The reference voltage circuit is configured to determine a reference voltage based on an output voltage from a power source. The ripple detector is configured to monitor an input voltage corresponding to a point along a power distribution line between the power source and a load, and detect the input voltage triggering a condition set forth based on the reference voltage. The counter is configured to record a number of the input voltage triggering the condition detected by the ripple detector, and send an alert based on the input voltage triggering the condition a preset number of times within a preset period.

According to an embodiment of the system, detecting the input voltage triggering the condition set forth based on the reference voltage includes at least one of detecting the input voltage exceeding the reference voltage, or detecting the input voltage falling below the reference voltage.

According to an embodiment of the system, the counter is configured to reset periodically according to the preset period.

According to an embodiment of the system, the alert is sent to a user or used by a controller to initiate a system response.

According to an embodiment of the system, the load is a motherboard of a computing system.

According to an embodiment of the system, the system further includes one or more ripple detectors. The one or more ripple detectors are configured to monitor a plurality of input voltages between the power source and the load.

According to an embodiment of the system, the system further includes a second ripple detector. The ripple detector is configured to monitor the input voltage when the load is in an active state. The second ripple detector is configured to monitor the input voltage when the load in a lower-power state.

According to an embodiment of the system, the ripple detector is configured to monitor the input voltage at a first setting, when the load is in an active state, and monitor the input voltage at a second setting, when the load in a lower-power state.

In yet a further exemplary embodiment, a method is provided for monitoring power stability. The method includes: provide a motherboard powered by a power source, provide a detection system comprising a reference voltage circuit, a ripple detector, and a counter, connecting the reference voltage circuit to the power source, connecting the ripple detector to a point along a power distribution line between the power source and the motherboard, and connecting the counter to a controller on the motherboard. The reference voltage circuit is configured to determine a reference voltage based on an output voltage from the power source. The ripple detector configured to monitor an input voltage corresponding to the point along the power distribution line, and detect the input voltage triggering a condition set forth based on the reference voltage. The counter is configured to record a number of the input voltage triggering the condition detected by the ripple detector, and send, to the controller, an alert based the input voltage triggering the condition a preset number of times within a preset period.

According to an embodiment of the method, detecting the input voltage triggering the condition set forth based on the reference voltage includes at least one of detecting the input voltage exceeding the reference voltage, or detecting the input voltage falling below the reference voltage.

According to an embodiment of the method, the counter is configured to reset periodically according to the preset period.

According to an embodiment of the method, the alert is used by the controller to initiate a system response.

### BRIEF DESCRIPTION OF THE DRAWINGS

Systems and methods for firmware update are described in detail below with reference to the attached drawing figures, wherein:

FIG. 1 illustrates a block diagram of a system according to one or more embodiments of the present disclosure.

FIG. 2 is a block diagram illustrating a detection system for monitoring power stability, according to one or more embodiments of the present disclosure.

FIG. 3A illustrates an example of a circuit for monitoring power stability, according to one or more embodiments of the present disclosure.

FIG. 3B illustrates example waveforms for various signals, according to one or more embodiments of the present disclosure.

FIG. 4A illustrates an example of a circuit for monitoring power stability, according to one or more embodiments of the present disclosure.

FIG. 4B illustrates example waveforms for various signals, according to one or more embodiments of the present disclosure.

FIG. 5 illustrates a method for setting up a detection system for monitoring power stability, according to one or more embodiments of the present disclosure.

FIG. 6 illustrates a method for monitoring power stability, according to one or more embodiments of the present disclosure.

### DETAILED DESCRIPTION

The following detailed description is exemplary in nature and is not intended to limit the disclosure or the application and uses of the described embodiments. Furthermore, there is no intention to be bound by any expressed or implied theory presented in the preceding background, summary and brief description of the drawings, or the following detailed description. Numerous specific details are set forth in order to provide a more thorough understanding of the disclosed technology. However, it will be apparent to one of ordinary skill in the art that the disclosed technology may be practiced without these specific details. In other instances, well-known features have not been described in detail to avoid unnecessarily complicating the description

Systems and methods are disclosed herein that relate to monitoring power stability utilizing a detection system. In at least one embodiment, the detection system utilizes a ripple detection device to monitor when the ripple in the supply power exceeds and/or falls below the limit of the output voltage from the power supply. The occurrences (or detected instances) are recorded by a counting device (e.g., a counter), and when the number of occurrences reaches a preset threshold, an alert signal is sent to a processing system, e.g., Baseboard Management Controller (BMC), to take appropriate action, e.g. replace wiring.

The detection system enables early identification of potential wiring degradation through ripple monitoring—without having to wait for insufficient voltage supply to systems components, such as a motherboard under high server load. This allows for timely alerts to operation and maintenance personnel, helping to proactively address aging wiring and prevent power delivery issues before they impact system reliability.

In one or more embodiments, the detection system monitors ripple to detect signs of aging in the wiring or connectors. In one or more embodiments, the detection system monitors multiple points along the power distribution line between the power source and the load.

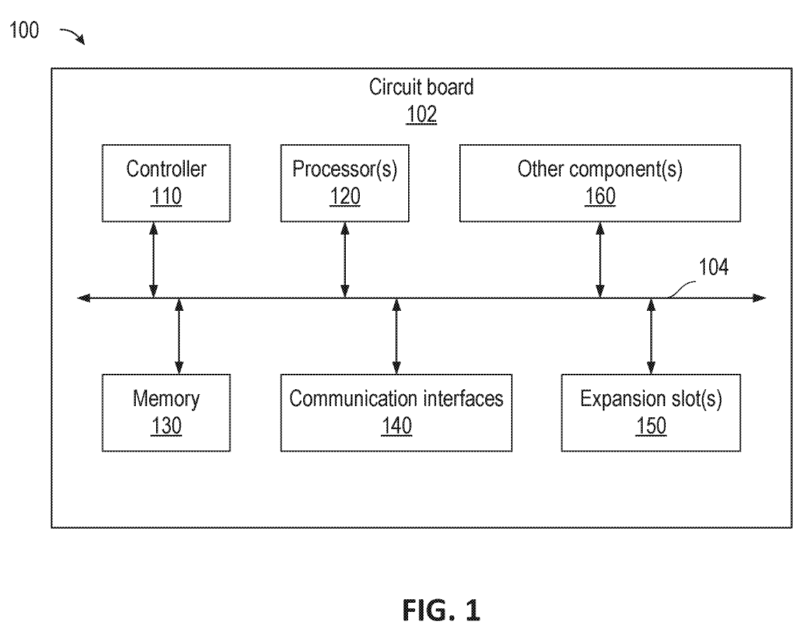

FIG. 1 illustrates a block diagram of a system 100, e.g., server, suitable for use in implementing embodiments of the present disclosure. It should be noted that the arrangements described herein, including this example, are provided for illustrative purposes only. Alternative configurations and components may be used in place of or in addition to those shown, and some components may be omitted entirely. Moreover, many of the elements described are functional in nature and can be implemented as standalone or distributed components or devices, either independently or in combination with other components, and located in various configurations. The functions discussed may be executed through hardware, firmware, and/or software, with processes typically performed by a processor running instructions stored in memory. Additionally, those skilled in the art will recognize that any system capable of performing the operations of the server system 100 falls within the scope and intent of the disclosed embodiments. The server system 100 can be housed in a rack-mounted chassis designed for optimal airflow and cooling, ensuring efficient heat dissipation during operation. Yet further, a person skilled in the art will recognize that the systems and methods described herein can be used with electronic systems and computer systems other than server systems.

The system 100 typically includes a circuit board 102, e.g., a motherboard, that may carry various components, including hardware, firmware, and/or software, which may be integrated with, attached to, connected to, or in communication with the motherboard. As shown in FIG. 1, the circuit board 102 carries at least one controller 110, such as a baseboard management controller (BMC), one or more processors 120, memory 130, communication interfaces 140, one or more expansion slots 150, and one or more other components 160. Such components and the circuit board 102 can communicate with one another through a bus 104, which may be integrated into the circuit board 102.

Processor(s) 120 may be configured to perform the operations in accordance with the instructions stored in memory 130. In certain embodiments, the memory 130 may be integral to the processor(s) 120. In other embodiments, the memory may in whole or in part be separate from the processor(s) 120. Processor(s) 120 may include any appropriate type of general-purpose or special-purpose microprocessor (e.g., a central processing unit (CPU) or graphics processing unit (GPU), respectively), digital signal processor, microcontroller, or the like. Memory 130 may be configured to store computer-readable instructions that, when executed by processor(s) 130, can cause processor(s) 120 to perform various operations disclosed herein and/or store data relating thereto.

Memory 130 may be any non-transitory type of mass storage, such as volatile or non-volatile, magnetic, semiconductor-based, tape-based, optical, removable, non-removable, or other type of storage device or tangible computer-readable medium including, but not limited to, a read-only memory (“ROM”), an electrical erasable programmable ROM (EEPROM), a flash memory, a dynamic random-access memory (“RAM”), and/or a static RAM. In certain embodiments, memory 130 may include multiple storage devices of various types.

Communication interfaces 140 may be configured to communicate information between system 100 and other devices or systems. For example, communication interfaces 140 may include an integrated services digital network (“ISDN”) card, a cable modem, a satellite modem, or a modem to provide a data communication connection. As another example, communication interfaces 140 may include a local area network (“LAN”) card to provide a data communication connection to a compatible LAN. As a further example, communication interfaces 140 may include a high-speed network adapter such as a fiber optic network adaptor, 10G Ethernet adaptor, or the like. Wireless links can also be implemented by communication interfaces 140. In such an implementation, communication interfaces 140 can send and receive electrical, electromagnetic, or optical signals that carry digital data streams representing various types of information via a network. The network can typically include a cellular communication network, a Wireless Local Area Network (“WLAN”), a Wide Area Network (“WAN”), or the like.

Controller 110, e.g., BMC, may include a processing unit, associated memory, and communication interfaces, and is configured to monitor and manage the system’s hardware components among other things. Controller 110 handles tasks such as remote system management, including hardware health monitoring, system event logging, and power control. Controller 110 can operate independently of the system’s 100 main processor (e.g., processor(s) 120), allowing for out-of-band management. Controller 110 may in certain embodiments facilitate communication with various sensors (e.g., other component(s) 160) on the circuit board 102 to track temperature, fan speed, voltage levels, and other critical parameters. Additionally, the controller 110 may include network interfaces and/or operate in conjunction with communication interfaces 140 to enable remote access for system administrators, providing a way to perform diagnostic tasks, power cycling, and firmware updates.

The expansion slot(s) 150 on the circuit board 102 may be used for connecting additional peripherals, such as GPUs, network cards, and more.

The other components 160 can include integrated components, replaceable components, and other suitable components. For example, these components may include but are not limited to sensors, cooling devices, power supply modules (and/or connectors), clock generators, chipsets, and more. In one or more embodiments, a chipset refers to a component or a group of components that manage communication between the CPU, memory (RAM), storage devices, network interfaces, and other peripherals.

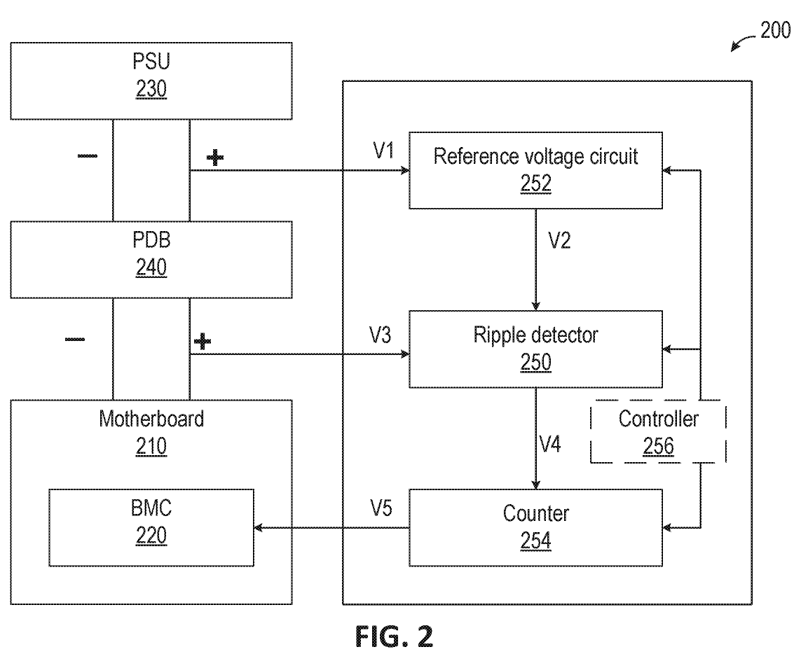

FIG. 2 is a block diagram illustrating a detection system 200 for monitoring power stability, according to one or more embodiments of the present disclosure. It should be noted that the arrangements described herein, including this example, are provided for illustrative purposes only. Alternative configurations and components may be used in place of or in addition to those shown, and some components may be omitted entirely. Moreover, many of the elements described are functional in nature and can be implemented as standalone or distributed components or devices, either independently or in combination with other components, and located in various configurations. The functions discussed may be executed through hardware, firmware, and/or software, with processes typically performed by a processor running instructions stored in memory.

As shown in FIG. 2, the detection system 200 includes a reference voltage circuit 252, a ripple detector 250, and a counter 254. Power to a motherboard 210 is monitored by the ripple detector 250, which sends relevant information to a BMC 220. In this implementation, the motherboard 210 represents the circuit board 102, and the BMC 220 represents the controller 110, as depicted in FIG. 1. The ripple detector 250 may be implemented as a discrete device, standalone circuitry, part of a larger circuit, or as an integrated circuit (e.g., packaged in a chip or module).

In this embodiment, the motherboard 210 is powered by a Power Supply Unit (PSU) 230 via a Power Distribution Board (PDB) 240. In at least one embodiment, the PSU 230 converts incoming alternating current (AC) power to regulated direct current (DC) power. The PDB 240 then receives the DC power and distributes it to various components on the motherboard 210. For example, the PDB 240 may supply power to the CPU, memory, chipset, and other integrated devices on the motherboard 210. In some examples, the motherboard 210, the PSU 230, the PDB 240, the ripple detector 250, and/or other peripheral circuits or components are included as part of the system 100. However, it should be noted that one or more PSUs 230 and/or one or more PDBs 240 may be integrated into the circuit for power delivery and distribution.

The lines between the PSU 230, the PDB 240, and the motherboard (MB) 210 represent the wiring for the main power supply connection. The ripple detector 250 is connected to the power delivery lines to monitor power stability at one or more connection points.

The ripple detector 250 is used to monitor the ripple voltage with reference to a stable reference voltage and a preset threshold. In at least one embodiment, a reference voltage circuit 252 is configured to provide a reference voltage (“V2”). For example, the reference voltage circuit 252 is connected to one or more output terminals of the PSU 230 to obtain a first voltage (“V1”) based on the output from the PSU 230. The voltage monitored by the ripple detector 250 is referred to as a third voltage (“V3,” also referred to as an input voltage). The ripple detector 250 is configured to detect abnormal instances, such as the ripple voltage exceeding and/or falling below the reference voltage threshold. In at least one embodiment, each time an abnormal condition is detected, the ripple detector 250 outputs a signal (“V4”). The signal output from the ripple detector 250 triggers a subsequent counter 254 to increment, thereby allowing the counter 254 to record the number of detected abnormal instances. In at least one embodiment, the counter 254 is configured to output a signal (“V5”) to, for example, the BMC 220 when the number of abnormal instances counted by the counter 254 reaches a predefined threshold within a preset time period. A signal may be an electrical signal, a message, or any other suitable form of notification or communication.

One or more ripple detectors 250 can be used to monitor power stability under various scenarios. For example, a ripple detector 250 can be configured to monitor and detect abnormal instances during active operation of system components, such as the motherboard 210 (e.g., while executing tasks). Additionally and/or alternatively, the same or a different ripple detector 250 can be configured to monitor and detect abnormal instances when the motherboard 210 is inactive or in a lower-power state (e.g., in a sleep mode).

The electrical characteristics of the motherboard 210, including current consumption and susceptibility to voltage ripple, vary significantly based on whether the motherboard 210 is active or idle. When the motherboard 210 is under full load, such as during high-performance tasks or active data processing, the motherboard 210 typically draws more current, which can lead to increased voltage fluctuations or ripple in the power delivery lines due to the higher demand. PSUs 230 and PDBs 240 are designed to maintain a stable voltage output under such conditions, but slight variations may still occur depending on the quality of the components and load regulation capabilities. Conversely, when the motherboard 210 is idle or in a low-power state, the overall current draw decreases significantly. In this scenario, the voltage supply tends to be more stable, with reduced ripple and noise, since fewer components are active and power demands are lower. On the other hand, the increased stability under low load provides a cleaner baseline, which can make it easier to detect abnormal fluctuations in the power supply, such as those resulting from aging wiring. The one or more ripple detectors 250 can be used to monitor abnormal instances across varying load conditions, thereby contributing to overall system reliability and performance.

In at least one embodiment, the ripple detector 250 is configured to detect abnormal instances under low load conditions by comparing the monitored voltage V3 to a reference voltage V2. Under normal conditions, the main power supply from the PSU 230 to the motherboard 210 will remain within the standard voltage limits. When under low load, if the monitored voltage V3 falls below the reference voltage V2, the counter 254 records the instance (e.g., corresponding to signal V4 from the ripple detector 250) without triggering an alarm, to avoid false detections. However, if the monitored voltage V3 falls below the reference voltage V2 multiple times within a preset period, an alarm signal (e.g., V5) is issued, indicating the need to replace the power supply cables. In at least one embodiment, the alarm signal V5 is received by the BMC 220, which then triggers an alarm to notify the user to take other action. For example, the BMC 220 may cause a warning message to be displayed on a display, transmit a warning message to the user (e.g., a message sent to a terminal device like a smartphone), or use any other suitable method to alert or notify the user.

As one illustrative example, the PSU’s 230 output voltage V1 is 12.2V, and its upper and lower limits are ±5%, corresponding to 12.81V and 11.59V, respectively. When the output voltage V1 is connected to the reference voltage circuit 252, the reference voltage circuit 252 produces a stable reference voltage of 2.5V, which is then supplied to the ripple detector 250 as the reference voltage V2. In at least one embodiment, the voltage V3 is drawn from the main power supply on the motherboard side and is converted through a DC level shifter (or other suitable component/circuit for converting/shifting DC voltage levels). The converted voltage V3 is slightly higher than 2.5V. When the wiring is not aged, the converted V3 voltage will not fall below 2.5V, and the ripple detector 250 will output a low signal. However, when the wiring or power supply interfaces have aged, whether under low or high load, the main power ripple on the motherboard side will generate power noise. The V3 voltage’s ripple or noise will intermittently fall below 2.5V, causing the ripple detector 250 to output a high signal V4. The high signal V4 causes the counter 254 to increment by one. Since ripple and noise below the reference voltage V2 can be detected under low load, the high-level signal V4 is sent and recorded in the counter 254. Once the number of high-level signals reaches a preset threshold, a high-level signal V5 is issued to notify the BMC 220 on the motherboard 210, which then triggers an alarm.

In one or more embodiments, one or more detection systems 200 may be implemented to monitor multiple points along a power distribution or delivery line, and/or the power supplied to various components on the motherboard 210 (or the circuit board 102). In one or more embodiments, a detection system 200 may include one or more reference circuits 252, one or more ripple detectors 250, and/or one or more counters 254, which together facilitate monitoring and detection at various points.

In at least one embodiment, the detection system 200 further includes a controller 256. The controller 256 is configured to control operation of the reference voltage circuit 252, the ripple detector 250, and/or the counter 254. For example, the controller 256 may adjust the reference voltage V2 generated by the reference voltage circuit 252 based on the first voltage V1. In some examples, the controller 256 may configure the ripple detector 250 to adjust the measurement setup for monitoring the converted voltage V3, such as by setting or modifying the sampling rate. Additionally and/or alternatively, the controller 256 may reset the counter 254 to reset the counter 254 at preset intervals (e.g., every 24 hours), or based on other predefined conditions. In one or more embodiments, the controller 256 may adjust the operation of one or more components in the detection system 200 based on the operating state of the motherboard 210, such as when the motherboard 210 is in an active state or a low-power state. For example, the detection system 200 may be configured to operate at a first setting when a load (e.g., the motherboard 210) is in an active state, or at a second setting when the load is in a low-power state. In some examples, the first and second settings may specify different preset periods, different reference voltages, or other suitable parameters.

The controller 256 may be implemented in various ways depending on system design requirements. In some embodiments, the controller 256 may be integrated within one of the components of the detection system 200, such as the reference voltage circuit 252, the ripple detector 250, or the counter 254. In other embodiments, the controller 256 may be a separate component that is part of the detection system 200 but functionally distinct from the other elements. Alternatively, the controller 256 may be implemented as an external controller that is communicatively coupled to one or more components within the detection system 200. For example, the external controller may be the BMC 220.

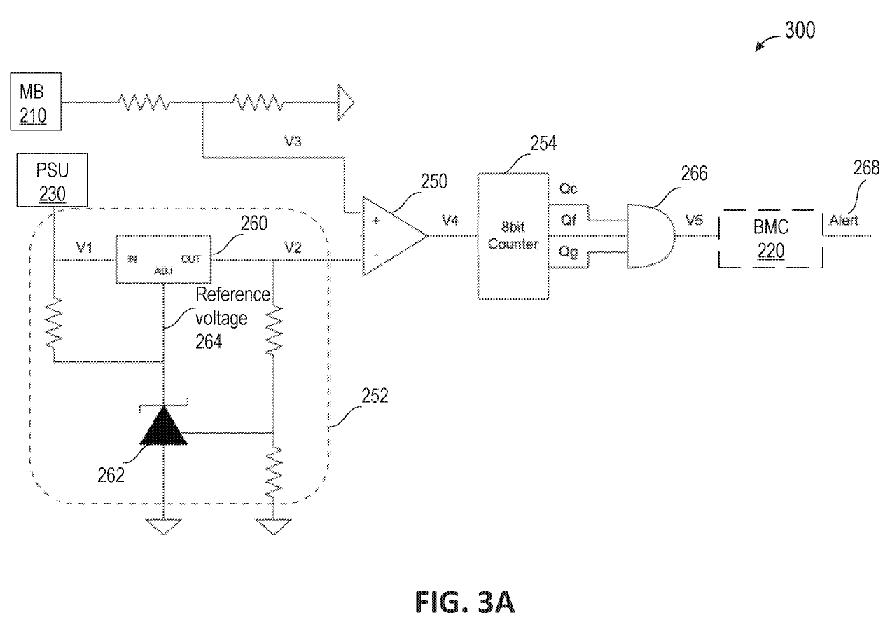

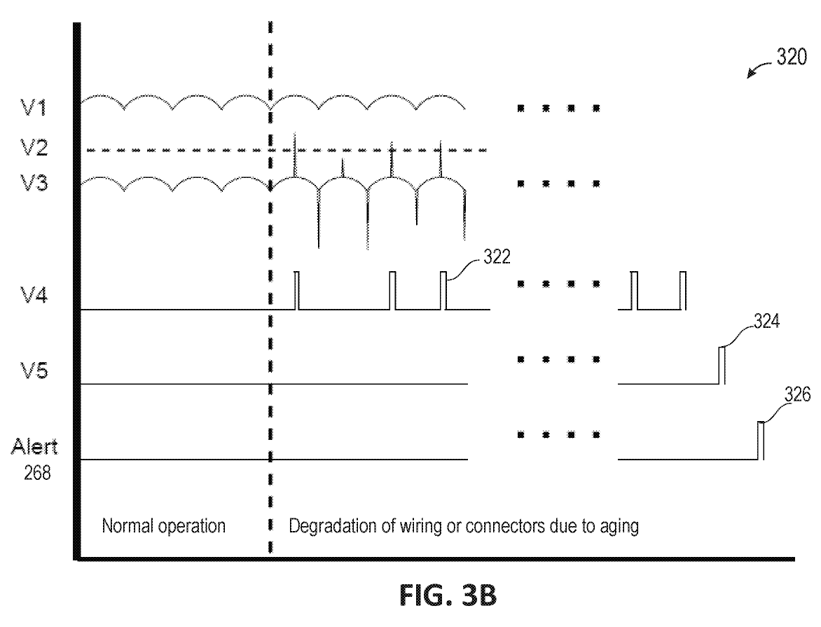

FIG. 3A illustrates an example of a circuit 300 for monitoring power stability for a motherboard, according to one or more embodiments of the present disclosure.

In this example, the ripple detector 250 is a three-terminal device, such as a comparator, and includes a first input terminal, a second input terminal, and a third output terminal. The first input terminal of the ripple detector 250 receives a voltage signal V3 from the motherboard side 210. The second input terminal of the ripple detector 250 receives a reference voltage V2 from a reference voltage circuit 252. The reference voltage circuit 252 is connected to the output of the PSU 230. The third output terminal of the ripple detector 250 is connected to a counter 254.

The reference voltage circuit 252 may include various electrical components, such as a low-dropout (LDO) regulator 260, a shunt regulator 262, and more. In this example, the LDO 260 is configured to receive the output voltage V1 from the PSU 230 as its input, along with a reference voltage 264 from the shunt regulator 262, in order to provide the reference voltage V2 for the ripple detector 250. In this configuration, the ripple detector 250 compares the input voltage V3 to the reference voltage V2 and generates a signal V4 when detecting that the input voltage V3 exceeds or falls below a threshold set based on the reference voltage V2. The signal V4 from the ripple detector 250 triggers the counter 254 to increment by one for each detected abnormal instance.

In this example, an eight-bit binary counter is used as the counter 254. The count of detected instances can be output through three output terminals, such as terminals “Qc,” “Qf,” and “Qg.” Each output terminal outputs a binary value of either one or zero. A logic AND gate 266 is connected to the three output terminals of the counter 254. In this setup, when the binary counter reaches a count where all three output terminals are high (i.e., a binary value of “111”), the AND gate 266 generates a signal V5, which is sent to the BMC 220. In response, the BMC 220 may send an alert 268 to notify a user or initiate a suitable system response.

FIG. 3B illustrates example waveforms 320 for various signals, according to one or more embodiments of the present disclosure. V1 represents the voltage input to the reference voltage circuit 252. V2 represents the reference voltage output from the reference voltage circuit 252. V3 represents the voltage drawn from the motherboard 210 and monitored by the ripple detector 250. V4 represents the output from the ripple detector 250, where each detected instance of abnormal ripple is visualized as a pulse 322. In this example, when the monitored voltage V3 exceeds the reference voltage V2, a pulse 322 is generated. V5 represents the output signal from the counter 254, with pulse 324 indicating that the counter has reached a predefined threshold within a preset time period. Alert 268 represents the alert output from the BMC 220 in response to monitoring results from the detection system 200, and may take the form of a pulse 326.

As shown in FIG. 3B, under normal operation, there may be no abnormal ripples or only a few. However, degradation of wiring or connectors due to aging can lead to many instances of abnormal ripples. Accordingly, the detection system 200 (or the ripple detector 250) may identify such issues by detecting abnormal ripples that exceed a threshold within a preset period.

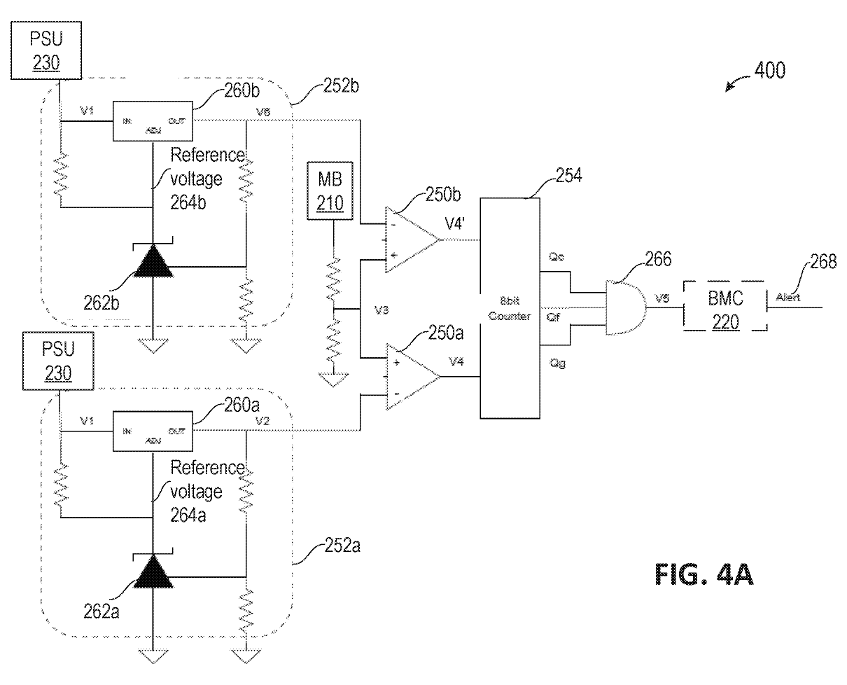

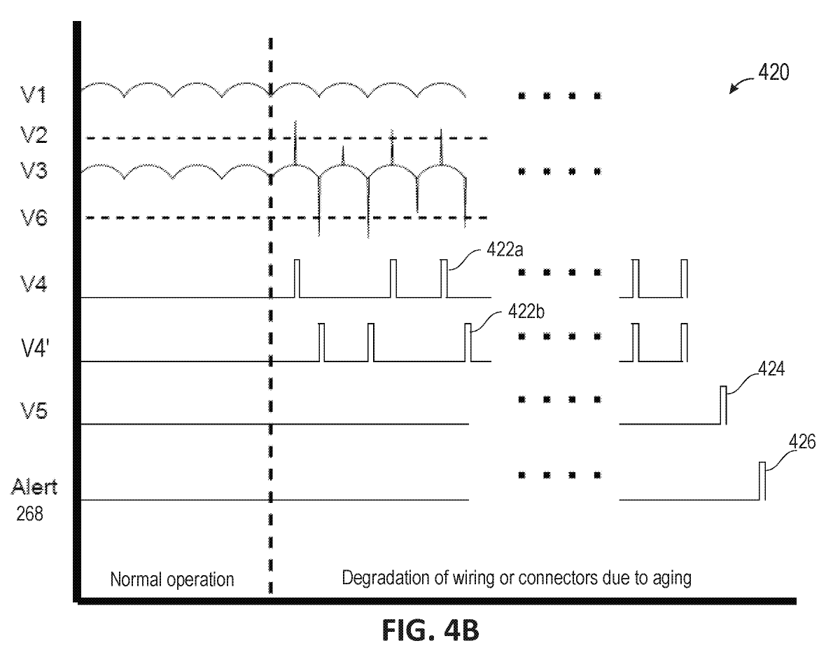

FIG. 4A illustrates an example of a circuit 400 for monitoring power stability for a motherboard, according to one or more embodiments of the present disclosure. The circuit 400 shares components in common with the circuit 300 as illustrated in FIG. 3A, and these components are labeled with the same numbers. The difference is that the circuit 400 implements two reference voltage circuits, 252a and 252b, each providing a distinct reference voltage—such as V2 and V6, respectively. Furthermore, two ripple detectors 250a and 250b are connected to the respective reference voltage circuits, 252a and 252b. The ripple detectors 250a and 250b are configured to detect abnormal instances, such as when ripple spikes exceed or fall below their respective reference voltages (e.g., V2 and V6). In this example, both ripple detectors 250a and 250b generate the signal V4 or V4’ when detecting abnormal instances, which triggers the counter 254 to increment by one for each detected abnormal instance. The signals V4 and V4’ may have identical or different voltage levels.

FIG. 4B illustrates example waveforms 420 for various signals, according to one or more embodiments of the present disclosure. Similarly, V1 represents the voltage input to the reference voltage circuits 252a and 252b. V2 and V6 represent the reference voltages output from the reference voltage circuits 252a and 252b, respectively. V3 represents the voltage drawn from the motherboard 210 and monitored by the ripple detectors 250a and 250b. V4 and V4’ represent the output from the ripple detectors 250a and 250b, respectively, where each detected instance of abnormal ripple is visualized as a pulse 422a or 422b. In this example, when the monitored voltage V3 exceeds the reference voltage V2, a pulse 422a is generated. When the monitored voltage V3 falls below the reference voltage V6, a pulse 422b is generated. V5 represents the output signal from the counter 254, with pulse 424 indicating that the counter has reached a predefined threshold within a preset time period. Alert 268 represents the alert output from the BMC 220 in response to monitoring results from the detection system 200, and may take the form of a pulse 426.

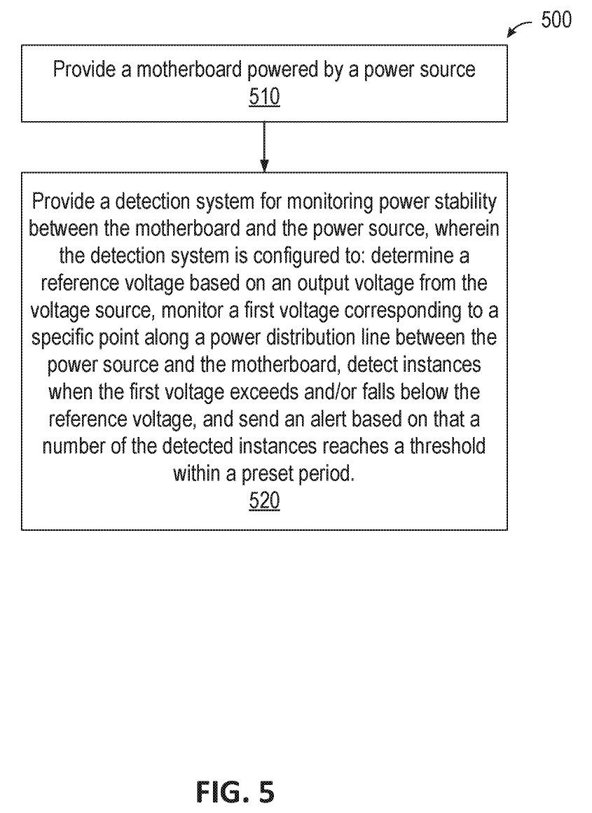

FIG. 5 illustrates a method 500 for setting up a detection system for monitoring power stability, according to one or more embodiments of the present disclosure. Method 500 may be performed alone or in combination with other processes in the present disclosure. It will be recognized that method 500 may be performed in any suitable environment and in any suitable order except where otherwise apparent. Alternative steps may be performed instead of or in addition to those shown, and some steps may be omitted entirely. In certain embodiments, controller 110 can be implemented as a BMC. Memory 130 may include a first area to store controller firmware 132 and a second area to store configuration data 136, as shown in FIG. 1B. In this example, the controller firmware is referred to as the firmware.

At stage 510, a motherboard powered by a power source is provided. For example, the power source may be one or more PSUs 230, as shown in FIG. 2. In at least one embodiment, the power source may include or operate in conjunction with one or more PDUs 240. The motherboard is provided as an example and may be replaced by another suitable circuit board (e.g., circuit 102 shown in FIG. 1) or another suitable computing system.

At stage 520, a detection system is provided for monitoring power stability between the motherboard and the power source. The detection system may be the detection system 200 as shown in FIG. 2, or may include one or more components disclosure therein. In at least one embodiment, the detection system is configured to determine a reference voltage based on an output voltage from the power source, monitor an input voltage corresponding to a specific point along a power distribution line between the motherboard and the power source, detect instances when the input voltage exceeds and/or falls below the reference voltage, and send an alert based on that the number of the detected instances reaches a threshold within a preset period. In at least one embodiment, the input voltage is drawn from the motherboard side.

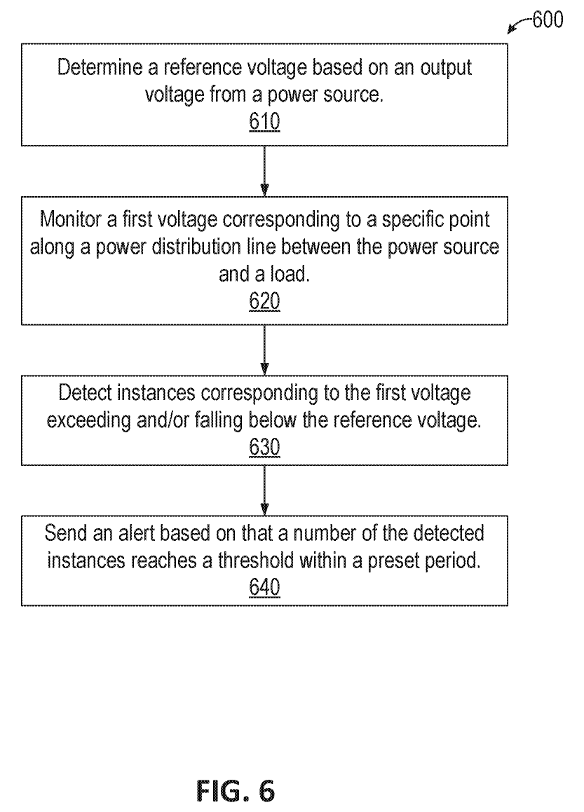

FIG. 6 illustrates a method 600 for monitoring power stability, according to one or more embodiments of the present disclosure. Method 600 may be performed by detection system 200 as illustrated in FIG. 2 or other suitable devices/circuits. Method 600 may be performed alone or in combination with other processes in the present disclosure. It will be recognized that method 600 may be performed in any suitable environment and in any suitable order except where otherwise apparent. Alternative steps may be performed instead of or in addition to those shown, and some steps may be omitted entirely. In this embodiment, method 600 is described with reference to the setup as depicted in FIG. 2.

At stage 610, the detection system 200 determines a reference voltage based on an output voltage from a power source. For example, the reference voltage circuit 252 in the detection system 200 receives output voltage V1 from the PSU 230 and then generates a reference voltage V2.

At stage 620, the detection system 200 monitors an input voltage corresponding to a specific point along a power distribution line between the power source and a load. For example, the load may be the motherboard 210. The ripple detector 250 in the detection system 200 monitors the input voltage V3 drawn from the motherboard side.

At stage 630, the detection system 200 detects instances corresponding to the input voltage exceeding and/or falling below the reference voltage. For example, the ripple detector 250 in the detection system 200 detects when the monitored voltage V3 falls below the reference voltage V2, which is provided by the voltage reference circuit 252. A counter 254 in the detection system 200 is used to record the number of instances detected by the ripple detector 250. In at least one embodiment, the counter 254 is configured to count the number of detected instances within a preset period. For example, a controller 256 (or the BMC 220 on the motherboard 210) may reset the counter 254 periodically.

At stage 640, the detection system 200 sends an alert based on that the number of detected instances reaches a threshold within a preset period. For example, when the number of instances counted by the counter 254 reaches a threshold within a preset period, the counter 254 may issue a signal to the BMC 220 to indicate an alert condition. In at least one embodiment, the BMC 220 may then send out an alert to notify a user or initiate an appropriate system response.

It is noted that the techniques described herein may be embodied in executable instructions stored in a non-transitory computer readable medium for use by or in connection with a processor-based instruction execution machine, system, apparatus, or device. It will be appreciated by those skilled in the art that, for some embodiments, various types of computer-readable media can be included for storing data. As used herein, a “computer-readable medium” includes one or more of any suitable media for storing the executable instructions of a computer program such that the instruction execution machine, system, apparatus, or device may read (or fetch) the instructions from the computer-readable medium and execute the instructions for carrying out the described embodiments. Suitable storage formats include one or more of an electronic, magnetic, optical, and electromagnetic formats. A non-exhaustive list of conventional exemplary computer-readable medium includes: a portable computer diskette; a random-access memory (RAM); a read-only memory (ROM); an erasable programmable read only memory (EPROM); a flash memory device; and optical storage devices, including a portable compact disc (CD), a portable digital video disc (DVD), and the like.

It should be understood that the arrangement of components illustrated in the attached Figures are for illustrative purposes and that other arrangements are possible. For example, one or more of the elements described herein may be realized, in whole or in part, as an electronic hardware component. The elements may be implemented in software, hardware, or a combination of software and hardware. Moreover, some or all of these other elements may be combined, some may be omitted altogether, and additional components may be added while still achieving the functionality described herein. Thus, the subject matter described herein may be embodied in many different variations, and all such variations are contemplated to be within the scope of the claims.

To facilitate an understanding of the subject matter described herein, many aspects are described in terms of sequences of actions. It will be recognized by those skilled in the art that the various actions may be performed by specialized circuits or circuitry, by program instructions being executed by one or more processors, or by a combination of both. The description herein of any sequence of actions is not intended to imply that the specific order described for performing that sequence must be followed. All methods described herein may be performed in any suitable order unless otherwise indicated herein or otherwise clearly contradicted by context.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

1. A method for monitoring power stability, comprising:
determining, by a detection system, a reference voltage based on an output voltage from a power source;
monitoring, by the detection system, an input voltage corresponding to a point along a power distribution line between the power source and a load;
detecting, by the detection system, the input voltage triggering a condition set forth based on the reference voltage; and
sending, by the detection system, an alert based on the input voltage triggering the condition a preset number of times within a preset period.

2. The method of claim 1, wherein detecting the input voltage triggering the condition set forth based on the reference voltage comprises at least one of:
detecting the input voltage exceeding the reference voltage; or
detecting the input voltage falling below the reference voltage.

3. The method of claim 1, wherein a number of times corresponding to the input voltage triggering the condition is counted by a counter in the detection system, and wherein the counter is reset periodically according to the preset period.

4. The method of claim 3, wherein sending the alert based on the input voltage triggering the condition the preset number of times within the preset period comprises:
sending, by the counter, a signal to a controller in response to the number of times counted by the counter reaching the preset number of times within the preset period; and
sending, by the controller, the alert to a user or initiate a system response.

5. The method of claim 1, wherein the load is a motherboard of a computing system.

6. The method of claim 1, further comprising:
monitoring, by the detection system, a plurality of input voltages between the power source and the load.

7. The method of claim 1, wherein the detection system comprises a first ripple detector and a second ripple detector,
wherein the first ripple detector is configured to monitor the input voltage when the load is in an active state; and
wherein the second ripple detector is configured to monitor the input voltage when the load in a lower-power state.

8. The method of claim 1, wherein the detection system is configured to:
monitor the input voltage at a first setting, when the load is in an active state; and
monitor the input voltage at a second setting, when the load in a lower-power state.

9. A system for monitoring power stability, comprising:
a reference voltage circuit configured to determine a reference voltage based on an output voltage from a power source;
a ripple detector configured to:
monitor an input voltage corresponding to a point along a power distribution line between the power source and a load; and
detect the input voltage triggering a condition set forth based on the reference voltage; and
a counter configured to:
record a number of the input voltage triggering the condition detected by the ripple detector; and
send an alert based on the input voltage triggering the condition a preset number of times within a preset period.

10. The system of claim 9, wherein detecting the input voltage triggering the condition set forth based on the reference voltage comprises at least one of:
detecting the input voltage exceeding the reference voltage; or
detecting the input voltage falling below the reference voltage.

11. The system of claim 9, wherein the counter is configured to reset periodically according to the preset period.

12. The system of claim 9, wherein the alert is sent to a user or used by a controller to initiate a system response.

13. The system of claim 9, wherein the load is a motherboard of a computing system.

14. The system of claim 9, further comprising one or more ripple detectors,
wherein the one or more ripple detectors are configured to monitor a plurality of input voltages between the power source and the load.

15. The system of claim 9, further comprising a second ripple detector,
wherein the ripple detector is configured to monitor the input voltage when the load is in an active state, and
wherein the second ripple detector is configured to monitor the input voltage when the load in a lower-power state.

16. The system of claim 9, wherein the ripple detector is configured to:
monitor the input voltage at a first setting, when the load is in an active state; and
monitor the input voltage at a second setting, when the load in a lower-power state.

17. A method for monitoring power stability:
provide a motherboard powered by a power source;
provide a detection system comprising a reference voltage circuit, a ripple detector, and a counter;
connecting the reference voltage circuit to the power source;
connecting the ripple detector to a point along a power distribution line between the power source and the motherboard; and
connecting the counter to a controller on the motherboard,
wherein the reference voltage circuit is configured to determine a reference voltage based on an output voltage from the power source,
wherein the ripple detector configured to:
monitor an input voltage corresponding to the point along the power distribution line; and
detect the input voltage triggering a condition set forth based on the reference voltage, and
wherein the counter is configured to:
record a number of the input voltage triggering the condition detected by the ripple detector; and
send, to the controller, an alert based the input voltage triggering the condition a preset number of times within a preset period.

18. The method of claim 17, wherein detecting the input voltage triggering the condition set forth based on the reference voltage comprises at least one of:
detecting the input voltage exceeding the reference voltage; or
detecting the input voltage falling below the reference voltage.

19. The method of claim 17, wherein the counter is configured to reset periodically according to the preset period.

20. The method of claim 17, wherein the alert is used by the controller to initiate a system response.
